(19) United States
(12) Patent Application Publication
(10) Pub. No.: US 2026/0150561 A1
(43) Pub. Date: May 28, 2026

(54) DISPLAY DEVICE

(71) Applicant: LG Display Co., Ltd., Seoul (KR)

(72) Inventors: Jin Woo HONG, Paju-si (KR); Sung Kyu HAN, Paju-si (KR)

(73) Assignee: LG Display Co., Ltd., Seoul (KR)

(21) Appl. No.: 19/246,408

(22) Filed: Jun. 23, 2025

(30) Foreign Application Priority Data
Nov. 28, 2024 (KR) 10-2024-0173188

(51) Int. Cl. H10K 59/80; H10K 59/35

(52) U.S. Cl. CPC H10K 59/879; H10K 59/353; H10K 59/8792

(57) ABSTRACT

A display device can include a bank insulating film positioned on a substrate and defining a plurality of emission regions, a plurality of light emitting elements arranged in the plurality of emission regions of the substrate, an encapsulation member positioned on the plurality of light emitting elements, a plurality of lenses arranged on the encapsulation member and positioned on the plurality of light emitting elements, and a lens planarization layer positioned on the plurality of lenses. Light emitting elements adjacent to each other among the plurality of light emitting elements are arranged to be staggered in a horizontal direction and a vertical direction.

### CROSS-REFERENCE TO RELATED APPLICATION

This application claims priority to and the benefit of Korean Patent Application No. 10-2024-0173188, filed in the Republic of Korea on Nov. 28, 2024, the disclosure of which is hereby expressly incorporated by reference in its entirety into the present application.

### BACKGROUND

### Field

The present disclosure relates to a display device.

### Discussion of the Related Art

A display device can include an organic light emitting display device (OLED) that emits light by itself, or a liquid crystal display device (LCD) that requires a separate light source.

Recently, a display device including a light emitting diode (LED) has gained attention as a next-generation display device. Since the light emitting diode (LED) is formed of an inorganic material rather than an organic material, it provides a faster lighting response time, superior light emitting efficiency, and the capability to display high-luminance images compared to the liquid crystal display device or the organic light emitting display device.

### SUMMARY OF THE DISCLOSURE

Generally, a display device provides images to a user. For example, a display device can include a plurality of light emitting elements. Each of the light emitting elements can emit light representing a specific color. For example, each light emitting element can include an emission layer positioned between a first electrode and a second electrode.

The display device can be configured to limit a viewing angle so that an image provided to the user is not perceived by others nearby. For example, the display device can include pixel lenses located on an encapsulation member covering the light emitting elements. The pixel lenses can overlap the light emitting elements. Accordingly, in the display device, light emitted from each light emitting element can be concentrated in a second direction that is perpendicular to a first direction.

An object of the embodiments of the present disclosure is to provide a display device capable of minimizing or preventing light leakage through lenses positioned above a plurality of light emitting elements that are arranged to be staggered.

The objectives of the embodiments of the present disclosure are not limited to those mentioned above, and other objectives not explicitly stated will be clearly understood by those skilled in the art from the following description.

A display device according to one or more embodiments of the present disclosure can include a bank insulating film positioned on a substrate and defining a plurality of emission regions; a plurality of light emitting elements arranged in the plurality of emission regions of the substrate; an encapsulation member positioned on the plurality of light emitting elements; a plurality of lenses arranged over the encapsulation member and positioned above the plurality of light emitting elements; and a lens planarization layer positioned on the plurality of lenses, wherein light emitting elements adjacent to each other among the plurality of light emitting elements are arranged to be staggered in a horizontal direction and a vertical direction.

A display device according to another embodiment of the present disclosure can include a display panel in which a first light emitting element and a second light emitting element are repeatedly arranged in a first direction, and the first light emitting element and the second light emitting element are repeatedly arranged in a second direction perpendicular to the first direction; a plurality of lenses positioned above the first light emitting element and the second light emitting element; and a lens planarization layer positioned on the plurality of lenses, wherein the first light emitting element and the second light emitting element are arranged to be staggered in a horizontal direction and a vertical direction.

The specific details of various examples according to the present disclosure, other than the means for solving the problems described above, are included in the following description and drawings.

According to aspects of the present disclosure, light leakage through adjacent light emitting elements can be minimized or prevented by arranging the adjacent light emitting elements to be staggered in a horizontal direction and a vertical direction.

The effects of the present disclosure are not limited to those described above, and other effects not explicitly mentioned will be clearly understood by those skilled in the art from the following description.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a diagram schematically illustrating a display device according to one or more embodiments of the present disclosure;

FIG. 2 is a partial view illustrating top surfaces of light emitting elements and lenses in a display device according to one embodiment of the present disclosure;

FIG. 3 is an enlarged view of portion A in FIG. 2;

FIG. 4 is a cross-sectional view taken along line I-I′ in FIG. 3;

FIG. 5 is an enlarged view of portion B in FIG. 4;

FIG. 6 is a partial view illustrating top surfaces of light emitting elements and lenses in a display device according to another embodiment of the present disclosure;

FIG. 7 is a diagram comparing light leakage in accordance with viewing angles, based on stagger widths between adjacent pixels and lenses, in a display device according to one embodiment of the present disclosure;

FIG. 8 is a diagram comparing light leakage in accordance with stagger distances between adjacent pixels in a display device according to one embodiment of the present disclosure; and

FIG. 9 is a diagram schematically illustrating leakage of light incident on adjacent pixels, according to stagger distances between adjacent pixels in a display device according to one embodiment of the present disclosure.

### DETAILED DESCRIPTION OF THE EMBODIMENTS

The advantages and features of the present disclosure, and methods of achieving them will become apparent upon reference to the embodiments described in detail below in conjunction with the accompanying drawings. However, the present disclosure is not limited to the following embodiments disclosed herein, but can be implemented in various different forms; rather, the present embodiments are provided to make the disclosure of the present disclosure complete and to enable those skilled in the art to fully comprehend the scope of the present disclosure.

The shapes, sizes, proportions, angles, numbers, and the like of elements shown in the drawings to illustrate embodiments of the present disclosure are merely illustrative and are not intended to be limiting. Identical reference numerals can designate identical components throughout the description. Further, in describing the present disclosure, detailed descriptions of related known technologies can be omitted so as not to obscure the essence of the present disclosure. The terms such as “including,” “having,” and “consisting of” as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts can be located between the two parts, unless “immediately,” “directly,” or “near to” is used.

When describing a temporal relationship, “after,” “subsequently to,” “following,” or, “before” describes a temporal antecedent or consequent relationship, which may not be continuous unless “immediately,” or “directly” is used.

The first, the second, and so on are used to describe various components, but these components are not limited by these terms. These terms are used only to distinguish one component from another. Therefore, the first component referred to below can be a second component within the technical spirit of the present disclosure.

Terms such as first, second, A, B, (a), or (b) can be used to describe elements of the embodiments of the present disclosure. Such terms are intended only to distinguish one component from another and are not intended to define the nature, sequence, order, or number of such components.

When a component is described as being “connected,” “coupled”, “accessed,” or “attached” to another component, it is to be understood that the component can be directly connected, coupled, accessed, or attached to the other component, but that there can also be other components interposed between the respective components which can be indirectly connected, coupled, accessed, or attached, unless specifically stated otherwise.

When a component is described as being “in contacted” or “overlapped” with another component, it is to be understood that the component can be in direct contacted or overlap with the other component, but that there can also be other components “interposed” between the respective components which can be indirect contacted or overlap with, unless specifically stated otherwise.

It should be understood that the term “at least one” includes all possible combinations of one or more related components. For example, the meaning of “at least one of the first, second, and third components” can be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but can refer to a broader range of orientations in which the configurations of the present disclosure can function. Further, the term “can” fully encompasses all the meanings and coverage of the term “may” and vice versa.

Each of the features of various embodiments of the present disclosure can be coupled or combined with one another in whole or in part, and can be technologically interlocked and operated in various ways, and each of the embodiments can be carried out independently or in conjunction with one another.

Hereinafter, various embodiments of the present disclosure will be described in detail with reference to the accompanying drawings. All the components of each display device according to all embodiments of the present disclosure are operatively coupled and configured.

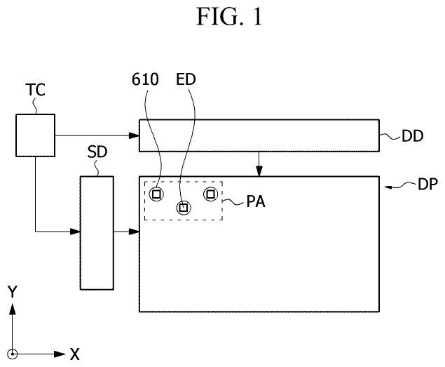

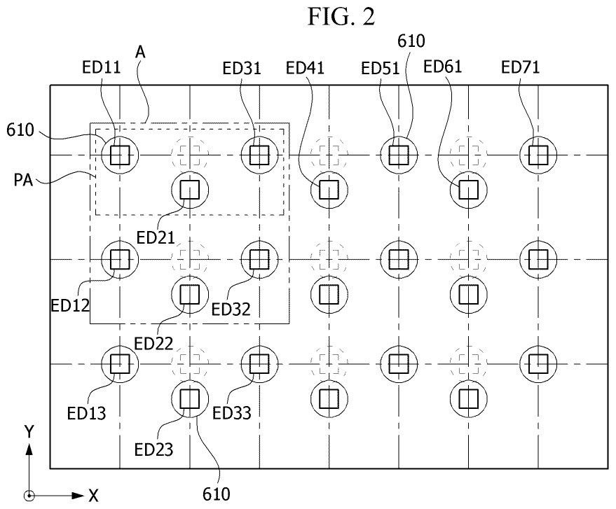

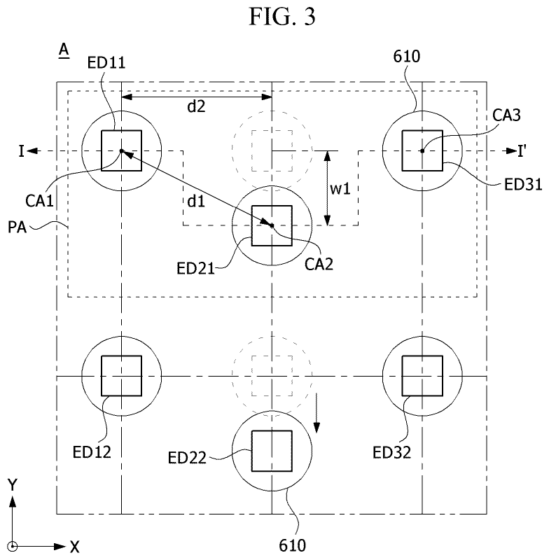

FIG. 1 is a diagram schematically illustrating a display device according to an embodiment of the present disclosure. FIG. 2 is a partial view illustrating top surfaces of light emitting elements and lenses in a display device according to one embodiment of the present disclosure. FIG. 3 is an enlarged view of portion A in FIG. 2.

Referring to FIG. 1, a display device according to an embodiment of the present disclosure can include a display panel DP, drivers SD, DD, and TC, and a plurality of lenses 610. The display panel DP can generate an image to be presented to a user. For example, the display panel DP can include a plurality of pixels PA. The drivers SD, DD, and TC can provide various signals necessary for image generation to the display panel DP. For example, the drivers SD, DD, and TC can include a scan driver SD, a data driver DD, and a timing controller TC.

The scan driver SD can sequentially apply scan signals to the display panel DP through scan lines. The data driver DD can apply a data signal to the display panel DP through data lines. The timing controller TC can control the scan driver SD and the data driver DD. For example, the timing controller TC can apply clock signals, reset clock signals, and start signals to the scan driver SD, and can apply digital video signals and a source timing control signal to the data driver DD.

The pixels PA of the display panel DP can be arranged at regular intervals in a first direction X and a second direction Y perpendicular to the first direction X. For example, the pixels PA can be arranged in a matrix form. Each pixel PA can include a plurality of light emitting elements ED. However, in the present disclosure, a case where one pixel PA includes three light emitting elements ED11, ED21, and ED31 that emit light of three colors is described as an example, but the present disclosure is not limited thereto. Hereinafter, the light emitting elements can be described by distinguishing them as the plurality of light emitting elements ED11, ED21, and ED31, but can also be collectively referred to as the light emitting element ED as needed. In addition, the light emitting elements ED11, ED31, ED51, . . . , EDm1 can be collectively referred to as the first light emitting element ED11 or as odd-numbered light emitting elements, and the light emitting elements ED21, ED41, ED61, . . . , EDn1 can be collectively referred to as the second light emitting element ED21 or as even-numbered light emitting elements.

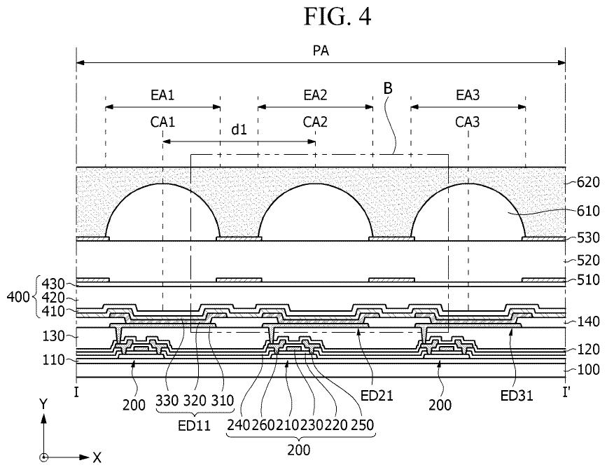

Each of the light emitting elements ED11, ED21, and ED31 constituting one pixel PA can implement a specific color, e.g., red, green, or blue. Thus, the light emitting elements ED11, ED21, and ED31 can emit light representing specific colors. For example, the light emitting element E11 located in a first emission region EA1 (see FIG. 4) can emit light implementing green, the light emitting element E21 located in a second emission region EA2 (see FIG. 4) can emit light implementing red, and the light emitting element ED31 located in a third emission region EA3 (see FIG. 4) can emit light implementing blue. However, the present disclosure is not limited thereto.

In addition, odd-numbered emission regions such as the first emission region EA1 and the third emission region EA3 can be collectively referred to as the first emission region EA1, and even-numbered emission regions such as the second emission region EA2 and a fourth emission region can be collectively referred to as the second emission region EA2.

For example, the light emitting elements ED11, ED21, and ED31 located in the first, second, and third emission regions EA1, EA2, and EA3 can be one of red, green, and blue light emitting elements. In addition, the light emitting elements ED11, ED21, and ED31, which are arranged adjacent to each other, can be light emitting elements that implement different colors.

Referring to FIGS. 2 and 3, in the display panel DP, the first light emitting element ED11 in the first emission region EA1 and the second light emitting element ED21 in the second emission region EA2 can be arranged repeatedly in a horizontal direction X, which is the first direction. In addition, the first light emitting element ED11 and the second light emitting element ED21 can be repeatedly arranged in a vertical direction Y, which is the second direction perpendicular to the first direction.

Specifically, the light emitting element ED can include first to n^{th} light emitting elements ED11 to EDxy arranged in a matrix (xy) direction. In this case, in the light emitting element EDxy, x can indicate a column position arranged in the first direction, e.g., the horizontal direction. Here, x can range from 1 to n, where n can be an integer equal to or greater than 1. In addition, y can indicate a row position arranged in the second direction, e.g., the vertical direction. y can range from 1 to n, where n can be an integer equal to or greater than 1. For example, the light emitting element ED23 can refer to a light emitting element positioned at the second column in the horizontal direction and the third row in the vertical direction.

Here, the light emitting elements ED11 to EDn1 can refer to light emitting elements arranged in the first to n^{th} columns in the first row. For example, the plurality of light emitting elements arranged in the first row can include light emitting elements ED11, ED21, and ED31, ED41, ED51, ED61, ED71, . . . , EDm1, and EDn1, where m and n can each be an integer equal to or greater than 1.

The plurality of light emitting elements arranged in the first row can include the light emitting elements ED11, ED21, ED31, ED41, ED51, ED71, . . . , EDm1, and EDn1. Specifically, odd-numbered light emitting elements arranged in the first row can include the light emitting elements ED11, ED31, ED51, ED71, . . . , and EDm1, and even-numbered light emitting elements arranged in the first row can include the light emitting elements ED21, ED41, ED61, ED81, . . . , and EDn1. Here, m and n can each be an integer equal to or greater than 1. For example, the light emitting element ED31 can refer to a light emitting element positioned at the third column in the first direction X, which is the horizontal direction, and the first row in the second direction Y, which is the vertical direction.

Referring to FIGS. 2 and 3, among the plurality of light emitting elements ED11, ED21, ED31, ED31, ED41, ED51, ED61, ED71, . . . , EDm1, and EDn1 arranged in the first row in the first direction X, which is the horizontal direction, the light emitting elements ED21, ED41, ED61, . . . , and EDn1 arranged in even-numbered columns in the first row can be staggered upward or downward in the vertical direction by a first stagger distance w1 from the same line of the horizontal direction with respect to the adjacent light emitting elements ED11, ED31, ED51, ED71, . . . , and EDm1 arranged in odd-numbered columns. In the present disclosure, a case where the light emitting elements arranged in even-numbered columns are staggered downward in the second direction Y, which is the vertical direction, by the first stagger distance w1 with respect to the light emitting elements in odd-numbered columns that are laterally adjacent thereto can be described as an example. However, the present disclosure is not limited thereto.

In one embodiment of the present disclosure, the light emitting elements ED21, ED41, ED61, . . . , and EDn1 arranged in even-numbered columns in the first row can be staggered downward in the vertical direction by the first stagger distance w1, which is constant in a straight line direction, with respect to the adjacent light emitting elements ED11, ED31, ED51, ED71, . . . , and EDm1 arranged in odd-numbered columns. Here, the first stagger distance w1 can be equal to or greater than at least one-half of the size of the light emitting element ED. However, the present disclosure is not limited thereto. For example, the light emitting elements ED can include the odd-numbered light emitting elements ED11, ED31, ED51, ED71, . . . , and EDm1, and the even-numbered light emitting elements ED21, ED41, ED61, . . . , and EDn1.

In another embodiment of the present disclosure, the odd-numbered light emitting elements ED can be staggered upward or downward in the vertical direction with respect to the even-numbered light emitting elements that are laterally adjacent thereto. The present disclosure is not limited thereto.

Specifically, in the first row, the even-numbered light emitting element ED21 can be staggered downward in the vertical direction by the first stagger distance w1 from a straight line of the horizontal direction with respect to the odd-numbered light emitting elements ED11 and ED31 that are laterally adjacent thereto, so that the even-numbered light emitting element ED21 can be spaced apart from the odd-numbered light emitting element ED11 by a first horizontal distance d1. In this case, if the light emitting elements ED21, ED41, ED61, . . . , and EDn1 in even-numbered columns are arranged to be aligned on the same horizontal line without being staggered with respect to the light emitting elements ED11, ED31, ED51, ED71, . . . , and EDm1 in odd-numbered columns that are laterally adjacent thereto, the light emitting elements ED21, ED41, ED61, . . . , and EDn1 in even-numbered columns can be spaced apart from the laterally adjacent light emitting elements ED11, ED31, ED51, ED71, . . . , and EDm1 in odd-numbered columns by a second horizontal distance d2.

As such, when the light emitting elements ED21 to EDn1 in even-numbered columns are staggered downward in the vertical direction by the first stagger distance w1 from the same horizontal line with respect to the laterally adjacent light emitting elements ED11 to EDm1 in odd-numbered columns, the first horizontal distance d1 between the light emitting elements ED21 to EDn1 in even-numbered columns and the laterally adjacent light emitting elements ED11 to EDm1 in odd-numbered columns can be greater than the second horizontal distance d2 between the light emitting elements ED21 to EDn1 in even-numbered columns and the laterally adjacent light emitting elements ED11 to EDm1 in odd-numbered columns when the light emitting elements ED21 to EDn1 in even-numbered columns are arranged to be aligned on the same horizontal line without being staggered with respect to the laterally adjacent light emitting elements ED11 to EDm1 in odd-numbered columns.

Accordingly, as the first horizontal distance d1 between the light emitting elements ED21 to EDn1 in even-numbered columns and the laterally adjacent light emitting elements ED11 to EDm1 in odd-numbered columns increases, light emitted from the light emitting elements ED21 to EDn1 in even-numbered columns and the laterally adjacent light emitting elements ED11 to EDm1 in odd-numbered columns can have a reduced effect on one another, thereby minimizing light leakage through the light emitting elements ED.

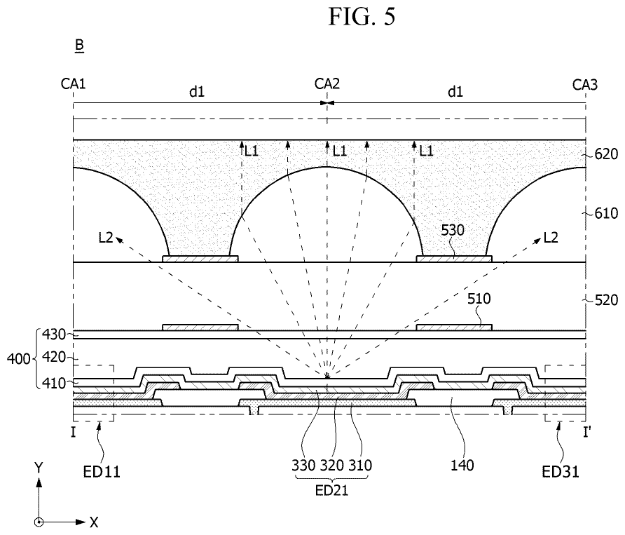

FIG. 4 is a cross-sectional view taken along line I-I′ in FIG. 3. FIG. 5 is an enlarged view of portion B in FIG. 4.

Referring to FIGS. 4 and 5, each light emitting element ED can be positioned on one of the emission regions EA1, EA2, and EA3 of a substrate 100 defined by a bank insulating film 140. The substrate 100 can include an insulating material. For example, the substrate 100 can include glass or plastic.

Driving circuits for controlling the operation of each light emitting element ED can be positioned between the substrate 100 and the light emitting elements ED, and between the substrate 100 and the bank insulating film 140. For example, each light emitting element ED can be electrically connected to one of the driving circuits. For example, each driving circuit can apply a driving current corresponding to the data signal to the corresponding light emitting element ED in response to a scan signal. Each driving circuit can include at least one thin film transistor 200. The thin film transistor 200 can include a semiconductor pattern 210, a gate insulating film 220, a gate electrode 230, a source electrode 250, and a drain electrode 260.

The semiconductor pattern 210 can be positioned close to the substrate 100. The semiconductor pattern 210 can include a semiconductor material. For example, the semiconductor pattern 210 can include an oxide semiconductor such as IGZO. The semiconductor pattern 210 can include a source region, a channel region, and a drain region. The channel region can be positioned between the source region and the drain region. The source region and the drain region can have lower resistance than the channel region. For example, the source region and the drain region can include conductive regions of the oxide semiconductor. The channel region can be a non-conductive region of the oxide semiconductor.

The gate insulating film 220 can be positioned on the semiconductor pattern 210. The gate insulating film 220 can extend outward beyond the semiconductor pattern 210. For example, the side surface of the semiconductor pattern 210 can be covered by the gate insulating film 220. For example, the gate insulating film 220 can include an insulating material. For example, the gate insulating film 220 can include an inorganic insulating material such as silicon nitride (SiN) or silicon oxide (SiO).

The gate electrode 230 can be positioned on the gate insulating film 220. The gate electrode 230 can include a conductive material.

The gate electrode 230 can be positioned on the gate insulating film 220. The gate electrode 230 can include a conductive material. For example, the gate electrode 230 can include a metal such as aluminum (Al), titanium (Ti), copper (Cu), chromium (Cr), molybdenum (Mo), or tungsten (W). The gate electrode 230 can be insulated from the semiconductor pattern 210 by the gate insulating film 220. For example, the channel region of the semiconductor pattern 210 can have an electrical conductivity corresponding to a voltage applied to the gate electrode 230.

An interlayer insulating film 240 can be positioned on the gate electrode 230. The interlayer insulating film 240 can extend outward beyond the gate electrode 230. For example, the side surface of the gate electrode 230 can be covered by the interlayer insulating film 240. The interlayer insulating film 240 can extend outward along the gate insulating film 220 beyond the semiconductor pattern 210. The interlayer insulating film 240 can include an insulating material. For example, the interlayer insulating film 240 can include an inorganic insulating material such as silicon nitride (SiN) or silicon oxide (SiO).

The source electrode 250 can include a conductive material. For example, the source electrode 250 can include a metal such as aluminum (Al), titanium (Ti), copper (Cu), chromium (Cr), molybdenum (Mo), or tungsten (W). The source electrode 250 can be insulated from the gate electrode 230. The source electrode 250 can be positioned on a different layer from the gate electrode 230.

The source electrode 250 can include a different material from the gate electrode 230. The source electrode 250 can be electrically connected to the source region of the semiconductor pattern 210. For example, the gate insulating film 220 and the interlayer insulating film 240 can include a source contact hole that exposes a portion of the source region of the semiconductor pattern 210. The source electrode 250 can be in direct contact with the source region of the semiconductor pattern 210 through the source contact hole.

The drain electrode 260 can include a conductive material. For example, the drain electrode 260 can include a metal such as aluminum (Al), titanium (Ti), copper (Cu), chromium (Cr), molybdenum (Mo), or tungsten (W). The drain electrode 260 can be insulated from the gate electrode 230. The drain electrode 260 can be positioned on a different layer from the gate electrode 230. For example, the drain electrode 260 can be positioned on the interlayer insulating film 240. The drain electrode 260 can include a different material from the gate electrode 230. The drain electrode 260 can be positioned on the same layer as the source electrode 250. The drain electrode 260 can include a different material from the gate electrode 230.

The drain electrode 260 can be positioned on the same layer as the source electrode 250. For example, the drain electrode 260 can include the same material as the source electrode 250. The drain electrode 260 can be insulated from the source electrode 250. For example, the drain electrode 260 can be spaced apart from the source electrode 250.

The drain electrode 260 can be electrically connected to the drain region of the semiconductor pattern 210. For example, the gate insulating film 220 and the interlayer insulating film 240 can include a drain contact hole that exposes a portion of the drain region of the semiconductor pattern 210. The drain electrode 260 can be in direct contact with the drain region of the semiconductor pattern 210 through the drain contact hole.

A buffer insulating film 110 can be positioned between the substrate 100 and the driving circuits. The buffer insulating film 110 can prevent contamination by the substrate 100 during the formation process of the thin film transistors 200. For example, the buffer insulating film 110 can cover the entire top surface of the substrate 100 facing the driving circuits.

The buffer insulating film 110 can include an insulating material. For example, the buffer insulating film 110 can include an inorganic insulating material such as silicon nitride (SiN) or silicon oxide (SiO). The buffer insulating film 110 can have a multilayer structure. For example, the buffer insulating film 110 can have a stacked structure including a layer formed of silicon nitride and a layer formed of silicon oxide.

A lower protective film 120 and a lower planarization layer 130 can be positioned between the driving circuits and the light emitting elements ED. The lower protective film 120 can prevent damage to the driving circuits caused by external impact and moisture. For example, the lower protective film 120 can extend along the surface of each driving circuit facing the light emitting elements ED. The lower planarization layer 130 can be positioned on the lower protective film 120. The lower planarization layer 130 can eliminate stepped portions caused by the driving circuits. For example, the thin film transistors 200 can be covered by the lower protective film 120 and the lower planarization layer 130.

The top surface of the lower planarization layer 130, opposite to the substrate 100, can be a flat plane. The lower protective film 120 and the lower planarization layer 130 can include an insulating material. The lower planarization layer 130 can include a different material from the lower protective film 120. For example, the lower protective film 120 can include an inorganic insulating material such as silicon nitride (SiN) or silicon oxide (SiO), and the lower planarization layer 130 can include an organic insulating material.

The light emitting elements ED can be positioned on the lower planarization layer 130. The light emitting elements ED can include a first electrode 310, an emission layer 320, and a second electrode 330 positioned on the substrate 100.

The first electrode 310 can include a conductive material. The first electrode 310 can include a highly reflective material. For example, the first electrode 310 can include a metal such as aluminum (Al) or silver (Ag). The first electrode 310 can have a multilayer structure. For example, the first electrode 310 can have a structure in which a reflective electrode made of a metal is located between transparent electrodes made of transparent conductive materials such as ITO or IZO.

The emission layer 320 can generate light having a luminance corresponding to a voltage difference between the first electrode 310 and the second electrode 330. For example, the emission layer 320 can include an emission material layer (EML) formed of a light emitting material. The light emitting material can include an organic material, an inorganic material, or a hybrid material. For example, the display panel DP of the display device according to an embodiment of the present disclosure can be an organic light emitting display panel including an organic light emitting material.

The emission layer 320 can have a multilayer structure. For example, the emission layer 320 can further include at least one of a hole injection layer (HIL), a hole transport layer (HTL), an electron transport layer (ETL), and an electron injection layer (EIL). Accordingly, in the display panel DP of the display device according to an embodiment of the present disclosure, the light emission efficiency of the emission layer 320 can be improved.

The second electrode 330 can include a conductive material. The second electrode 330 can include a different material from the first electrode 310. The second electrode 330 can be a transparent electrode having a higher transmittance than the first electrode 330. For example, the second electrode 330 can include a transparent conductive material such as ITO or IZO. Accordingly, in the display panel DP of the display device according to an embodiment of the present disclosure, light generated by the emission layer 320 of each of the emission regions EA1, EA2, and EA3 can be emitted to the outside through the second electrode 330 of the corresponding emission region.

The light emitting elements ED11, ED21, and ED31 of the emission regions EA1, EA2, and EA3 can be independently controlled. For example, the first electrode 310 positioned in each of the emission regions EA1, EA2, and EA3 can be spaced apart from the first electrodes 310 located in the adjacent emission regions EA1, EA2, and EA3.

The bank insulating film 140 can be positioned between the first electrodes 310 of the adjacent emission regions EA1, EA2, and EA3. The bank insulating film 140 can include an insulating material. For example, the bank insulating film 140 can include an organic insulating material.

The first electrode 310 positioned in each of the emission regions EA1, EA2, and EA3 can be insulated from the first electrodes 310 positioned in the adjacent emission regions EA1, EA2, and EA3 by the bank insulating film 140. For example, the bank insulating film 140 can cover the edge of the first electrode 310 positioned in each of the emission regions EA1, EA2, and EA3. The emission layer 320 and the second electrode 330 of each of the emission regions EA1, EA2, and EA3 can be sequentially stacked on a partial region of the first electrode 310 exposed by the bank insulating film 140. For example, the emission regions EA1, EA2, and EA3 can be defined by the bank insulating film 140.

The emission regions EA1, EA2, and EA3 of each pixel PA can implement different colors. For example, the emission layer 320 positioned in each of the emission regions EA1, EA2, and EA3 can be spaced apart from the emission layers 320 positioned in the adjacent emission regions EA1, EA2, and EA3. The emission layer 320 positioned in each of the emission regions EA1, EA2, and EA3 can include a different material from the emission layers 320 positioned in the adjacent emission regions EA1, EA2, and EA3. For example, the first light emitting element ED11 positioned in the first emission region EA1 can emit light implementing green, the second light emitting element ED21 positioned in the second emission region EA2 can emit light implementing red, and the third light emitting element ED31 positioned in the third emission region EA3 can emit light implementing blue. The present disclosure is not limited thereto.

The first to third emission regions EA1, EA2, and EA3, in which the light emitting elements of each pixel PA are positioned, can have the same area or different areas. For example, when they have different areas, the second emission region EA2 that implements red color can have a larger area than the first emission region EA1 that implements green color, and the third emission region EA3 that implements blue color can have a larger area than the second emission region EA2. In the present disclosure, a case where the first to third emission regions EA1, EA2, and EA3 of each pixel PA have the same area will be described as an example. However, the present disclosure is not limited thereto.

The first emission region EA1 can be an upper region overlapping the odd-numbered first light emitting element ED11 positioned in the first column and the first row. The second emission region EA2 can be an upper region overlapping the even-numbered second light emitting element ED21 positioned in the second column and the first row. The third emission region EA3 can be an upper region overlapping the odd-numbered third light emitting element ED31 positioned in the third column and the first row.

The second emission region EA2, in which the second light emitting element ED21 is located, can be positioned between the first and third emission regions EA1 and EA3, in which the first and third light emitting elements ED11 and ED31 are located. Here, with respect to the first and third emission regions EA1 and EA3 arranged in the first direction X, which is the horizontal direction, the second emission region EA2 can be staggered downward in the second direction Y, which is the vertical direction, by the first stagger distance w1. Alternatively, the second emission region EA2 can be staggered to the right in the second direction Y, which is the vertical direction, by the first stagger distance w1 relative to the first and third emission regions EA1 and EA3 along the first direction X, which is the horizontal direction.

The first emission region EA1, the second emission region EA2, and the third emission region EA3 can be repeatedly and alternately positioned in the first direction X, which is the horizontal direction, and the second direction Y, which is the vertical direction.

A voltage applied to the second electrode 330 positioned in each of the emission regions EA1, EA2, and EA3 can be the same as a voltage applied to the second electrodes 330 positioned in the adjacent emission regions EA1, EA2, and EA3. For example, the second electrode 330 positioned in each of the emission regions EA1, EA2, and EA3 can include the same material as the second electrodes 330 positioned in the adjacent emission regions EA1, EA2, and EA3.

The second electrode 330 positioned in each of the emission regions EA1, EA2, and EA3 can be in direct contact with the second electrodes 330 positioned in the adjacent emission regions EA1, EA2, and EA3.

The second electrodes 330 of the light emitting elements ED11, ED21, and ED31 positioned in the respective emission regions EA1, EA2, and EA3 can extend onto the bank insulating film 140.

The bank insulating film 140 and the light emitting elements ED11, ED21, and ED31 can be supported by the substrate 100. For example, each of the light emitting elements ED11, ED21, and ED31 can be positioned on one of the emission regions EA1, EA2, and EA3 of the substrate 100 defined by the bank insulating film 140. The substrate 100 can include an insulating material. For example, the substrate 100 can include glass or plastic.

The bank insulating film 140 can be in direct contact with the lower planarization layer 130 between the adjacent first electrodes 310. Each light emitting element ED can be electrically connected to one of the thin film transistors 200. For example, the lower protective film 120 and the lower planarization layer 130 can include electrode contact holes that expose a portion of the drain electrode 260 of each thin film transistor 200. The first electrode 310 of each light emitting element ED can be in direct contact with the drain electrode 260 of the corresponding thin film transistor 200 through one of the electrode contact holes.

An encapsulation member 400 can be positioned on the bank insulating film 140 and the light emitting elements ED11, ED21, and ED31.

The encapsulation member 400 can prevent damage to the light emitting elements ED caused by external impact and moisture. The encapsulation member 400 can have a multilayer structure. For example, the encapsulation member 400 can include a first encapsulation layer 410, a second encapsulation layer 420, and a third encapsulation layer 430 that are sequentially stacked. The first encapsulation layer 410, the second encapsulation layer 420, and the third encapsulation layer 430 can include an insulating material. However, the present disclosure is not limited thereto.

The second encapsulation layer 420 can include a different material from the first encapsulation layer 410 and the third encapsulation layer 430. For example, the first encapsulation layer 410 and the third encapsulation layer 430 can include an inorganic insulating material such as silicon nitride (SiN) or silicon oxide (SiO), while the second encapsulation layer 420 can be made of an organic insulating material. However, the present disclosure is not limited thereto.

In addition, a first black matrix 510 can be positioned on the encapsulation member 400. The first black matrix 510 can have an opening corresponding to each of the light emitting elements ED11, ED21, and ED31. The first black matrix 510 can be formed of a black resin, chromium oxide, or the like. However, the present disclosure is not limited thereto. The first black matrix 510 can function to control an optical path of light.

An upper planarization layer 520 can be positioned on the encapsulation member 400 and the first black matrix 510. The upper planarization layer 520 can have a thickness ranging from several micrometers to several tens of micrometers and can be formed of an organic insulating material. However, the present disclosure is not limited thereto.

In addition, the upper planarization layer 520 can be used as an optical gap layer. The optical gap layer can function to improve the efficiency of the lens 610 by securing an optical gap between the light emitting element ED and the lens 610 positioned on the upper planarization layer 520, so that light from the light emitting element ED passes through the lens 610 and is refracted in a specific direction.

In one example, the upper planarization layer 520 used as the optical gap layer can be formed of photo acryl, benzocyclobutene (BCB), polyimide (PI), or polyamide (PA), but is not limited thereto.

As such, since the upper planarization layer 520 having a flat top surface is provided on the top of the encapsulation member 400 on the light emitting element ED, the light emitting elements ED can be effectively prevented from being damaged by external impact and moisture.

A second black matrix 530 can be positioned on the upper planarization layer 520 used as the optical gap layer. The second black matrix 530 can be positioned to overlap the first black matrix 510. The second black matrix 530 can have an opening corresponding to each of the light emitting elements ED11, ED21, and ED31, and the width of the second black matrix 530 can be the same as or smaller than that of the first black matrix 510. However, the present disclosure is not limited thereto.

The second black matrix 530 can be formed of a metallic material. However, the present disclosure is not limited thereto. The second black matrix 530 can function as an in-cell touch electrode, e.g., a touch on electrode (ToE), as well as control an optical path of light.

The lenses 610 respectively corresponding to the light emitting elements ED11, ED21, and ED31 can be positioned on the second black matrix 530. The lens 610 can have a semicircular cross-sectional shape. The lens 610 can be positioned to overlap the first black matrix 510 and the second black matrix 530.

Light emitted from each light emitting element ED can be outputted at a specific angle by the lenses 610, thereby limiting a viewing angle.

The lens 610 can be positioned in the emission region EA1 where the light emitting element ED11 of each pixel PA of the display panel DP is positioned. Although the light emitting element ED11 has been described in the present disclosure, the light emitting element ED11 can be equally applied to other light emitting elements in addition to the light emitting element ED11.

The lenses 610 can be positioned on the paths of light emitted from the respective light emitting elements ED11 of the display panel DP. The lenses 610 can be located at positions overlapping the light emitting elements ED.

The lenses 610 can have a semicircular shape with a flat surface that is in direct contact with the upper planarization layer 520 of the display panel DP. The plurality of the lenses 610 can be arranged at regular intervals in the first direction X and the second direction Y to constitute the display panel DP. In this case, the lenses 610 can be positioned to overlap the light emitting elements ED, which are arranged corresponding to the emission areas EA.

Accordingly, in the display device according to an embodiment of the present disclosure, light traveling toward central axes CA1, CA2, and CA3 of the lenses 610 can be concentrated. In addition, in the display device according to an embodiment of the present disclosure, the viewing angle toward the side portions of the lenses 610 can be limited.

A lens planarization layer 620 can be positioned on the lenses 610. Specifically, the lens planarization layer 620 can be positioned on the lenses 610 and the second black matrix 530. For example, the lenses 610 can be covered by the lens planarization layer 620. The lens planarization layer 620 can be in direct contact with the surface of each lens 610 opposite to the display panel DP. The lens planarization layer 620 can include an insulating material. For example, the lens planarization layer 620 can include an organic insulating material. Stepped portions caused by the lenses 610 can be eliminated by the lens planarization layer 620. For example, the top surface of the lens planarization layer 620, opposite to the encapsulation member 400 of the display panel DP, can be a flat plane.

The refractive index of the lens planarization layer 620 can be smaller than the refractive index of each lens 610. Accordingly, in the display device according to an embodiment of the present disclosure, light L1 and L2 emitted from the light emitting elements ED11, ED21, and ED31 of the respective emission areas EA1, EA2, and EA3 in an outward direction of the corresponding emission areas EA1, EA2, and EA3 can pass through edge portions of the respective lenses 610 and can be refracted at the boundary between the corresponding lenses 610 and the lens planarization layer 620 in a direction parallel to the light L1 emitted in a frontward direction of the corresponding emission areas EA1, EA2, and EA3.

For example, referring to FIG. 5, in the display device according to an embodiment of the present disclosure, among the light L1 and L2 emitted from the light emitting element ED21, the light L1 can travel in a direction parallel to the frontward direction of the corresponding emission area EA2 by the lens 610 and the lens planarization layer 620.

In contrast, the light L2 emitted from the light emitting element ED21 can travel toward the adjacent light emitting elements ED11 and ED31. However, according to one embodiment of the present disclosure, since the light emitting element ED21 that emits the light L1 and L2 is positioned to be staggered downward in the vertical direction, which is the second direction Y, by the first stagger distance w1, with respect to the light emitting elements ED11 and ED31 that are adjacent to the left and right sides thereof in the horizontal direction, which is the first direction X, the first horizontal distance d1 can be present between the central axis CA2 of the light emitting element ED21 and the central axes CA1 and CA3 of the light emitting elements ED11 and ED31.

Therefore, the first horizontal distance d1 between the light emitting element ED21, which is staggered by the first stagger distance w1 in the vertical direction Y with respect to the light emitting elements ED11 and ED31, and the light emitting elements ED11 and ED31 can be greater than the second horizontal distance d2 between the central axis CA2 of the light emitting element ED21 and the central axes CA1 and CA3 of the light emitting elements ED11 and ED31 in a case where the light emitting element ED21 is aligned on the same line in the horizontal direction, which is the first direction X, with the laterally adjacent light emitting elements ED11 and ED31.

As a result, since the first horizontal distance d1 between the light emitting element ED21 and the light emitting elements ED11 and ED31 becomes greater than the conventional second horizontal distance d2, light leakage of the light L2 emitted the light emitting element ED21 toward the lenses 610 positioned above the adjacent light emitting elements ED11 and ED31 can be minimized due to the first horizontal distance d1.

Specifically, among the light L1 and L2 emitted from the light emitting element ED21, the light L1 can travel in a direction parallel to the frontward direction of the corresponding emission area EA2 by the lens 610, regardless of the first horizontal distance d1.

In contrast, portion of the light L2 emitted from the light emitting element ED21 can leak toward the laterally adjacent light emitting elements ED11 and ED31 due to the first horizontal distance d1. However, since the light emitting element ED21 is spaced farther apart from the laterally adjacent light emitting elements ED11 and ED31 by the first horizontal distance d1, which is greater than the conventional second horizontal distance d2, light leakage of the light L2 emitted from the light emitting element ED21 toward the laterally adjacent light emitting elements ED11 and ED31 can be minimized.

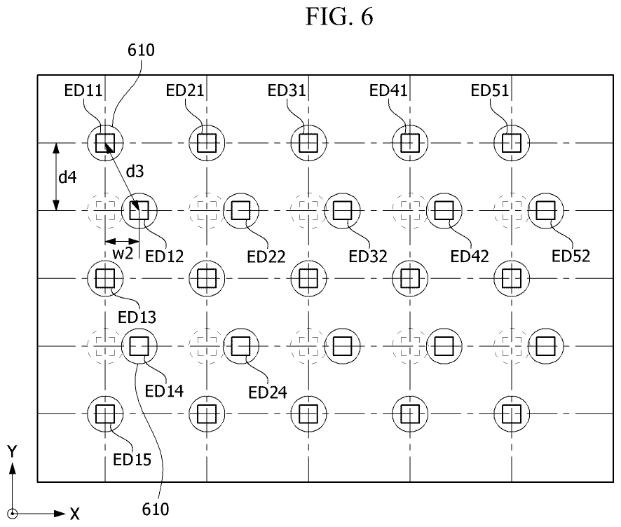

FIG. 6 is a partial view illustrating top surfaces of light emitting elements and lenses in a display device according to another embodiment of the present disclosure.

Referring to FIG. 6, the display device according to another embodiment of the present disclosure can differ from that of one embodiment of the present disclosure shown in FIG. 2 in that, among the plurality of light emitting elements ED11, ED12, ED13, . . . , ED1m, and ED1n arranged in rows in the second direction Y, which is the vertical direction, the light emitting elements ED12, ED14, ED16, . . . , and ED1m arranged in even-numbered rows can be spaced apart in the first direction X, which is the horizontal direction, by a second stagger distance w2 with respect to the light emitting elements ED11, ED13, ED15, . . . , and ED1n arranged in odd-numbered rows that are vertically adjacent thereto.

In the present disclosure, a case where the light emitting elements ED12, ED14, ED16, . . . , and ED1m in even-numbered rows are spaced to the right by the second stagger distance w2 from the light emitting elements ED11, ED13, ED15, . . . , and ED1n in odd-numbered rows can be described as an example. However, the present disclosure is not limited thereto.

In addition, another embodiment of the present disclosure can have the same configuration as one embodiment of the present disclosure shown in FIG. 2, except for a configuration in which the light emitting elements ED12, ED14, ED16, . . . , and ED1m in even-numbered columns are spaced to the right by the second stagger distance w2 with respect to the light emitting elements ED11, ED13, ED15, . . . , and ED1n in odd-numbered columns.

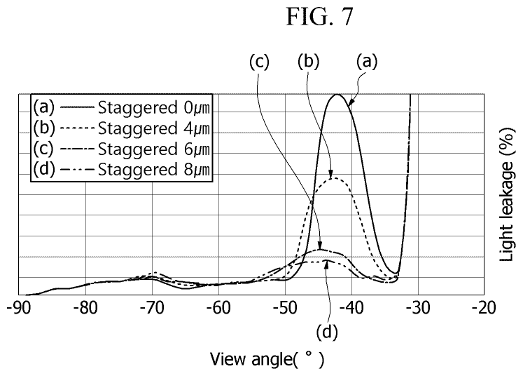

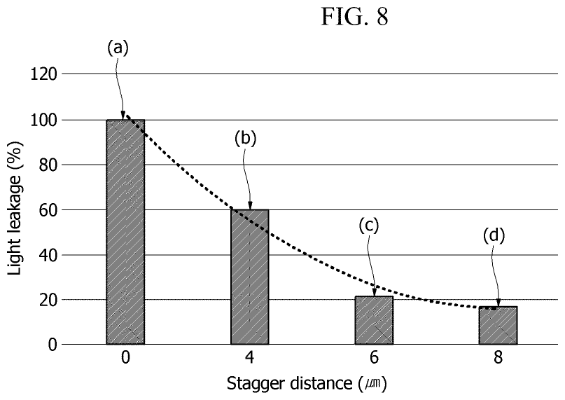

FIG. 7 is a diagram comparing light leakage in accordance with viewing angles, based on stagger widths between adjacent pixels and lenses, in a display device according to one embodiment of the present disclosure. FIG. 8 is a diagram comparing light leakage in accordance with stagger distances between adjacent pixels in a display device according to one embodiment of the present disclosure.

Referring to (a) in FIGS. 7 and 8, in a case where the light emitting elements ED21, ED41, ED61, . . . , and EDm1 in even-numbered columns are not staggered with respect to the light emitting elements ED11, ED31, ED51, . . . , and EDn1 in odd-numbered columns that are arranged adjacent thereto, but are instead arranged on the same line in the first direction X, which is the horizontal direction, it can be observed that light leakage occurs at a high level of about 100% at a viewing angle ranging from about 30° to 50°.

In contrast, referring to (b) in FIGS. 7 and 8, in a case where the light emitting elements ED21, ED41, ED61, . . . , and EDn1 in even-numbered columns are staggered by the first stagger distance w1 of about 4 μm in the second direction Y, which is the vertical direction, with respect to the light emitting elements ED11, ED31, ED51, . . . , and EDm1 in odd-numbered columns that are arranged adjacent thereto, it can be observed that light leakage at a viewing angle between about 30°and 50°is reduced to about 60%, compared to the case of (a) in FIGS. 7 and 8 in which the light emitting elements are not staggered. In this case, when the first stagger distance w1 is about 4 μm, the first horizontal distance d1 between the plurality of even-numbered column light emitting elements ED and the adjacent odd-numbered column light emitting elements ED can be greater than the conventional second horizontal distance d2 in the case where the light emitting elements are not staggered.

Therefore, according to the present disclosure, since, with respect to the plurality of light emitting elements ED and the lenses 610 positioned thereabove, the adjacent light emitting elements and the lenses 610 positioned thereabove are arranged in a staggered manner vertically and horizontally, light leakage occurring through the lenses 610 positioned above the adjacent light emitting elements can be reduced.

Referring to (c) in FIGS. 7 and 8, in a case where the light emitting elements ED21, ED41, ED61, . . . , and EDn1 in even-numbered columns are staggered by the first stagger distance w1 of about 6 μm in the second direction Y, which is the vertical direction, with respect to the light emitting elements ED11, ED31, ED51, . . . , and EDm1 in odd-numbered columns that are arranged adjacent thereto, it can be observed that light leakage at a viewing angle between about 30° and 50° is reduced to about 20%, compared to the case of (a) in FIGS. 7 and 8 in which the light emitting elements are not staggered. In this case, when the first stagger distance w1 is about 6 μm, the first horizontal distance d1 between the plurality of even-numbered column light emitting elements and the adjacent odd-numbered column light emitting elements can be greater than the conventional second horizontal distance d2 in the case where the light emitting elements are not staggered.

Therefore, according to the present disclosure, since the plurality of light emitting elements ED vertically overlap the plurality of lenses 610, and the adjacent light emitting elements ED are staggered by about 6 μm, light leakage through the lenses 610 positioned above the adjacent light emitting elements ED can be reduced compared to a case where the adjacent light emitting elements ED are staggered by about 4 μm.

Referring to (d) in FIGS. 7 and 8, in a case where the light emitting elements ED21, ED41, ED61, . . . , and EDn1 in even-numbered columns are staggered by the first stagger distance w1 of about 8 μm in the second direction Y, which is the vertical direction, with respect to the light emitting elements ED11, ED31, ED51, . . . , and EDm1 in odd-numbered columns that are arranged adjacent thereto, it can be observed that light leakage at a viewing angle between about 30° and 50° is reduced to about 17%. In this case, when the first stagger distance w1 is about 8 μm, the first horizontal distance d1 between the plurality of even-numbered column light emitting elements ED21 and the adjacent odd-numbered column light emitting elements ED11 and ED31 can be greater than the conventional second horizontal distance d2 in the case where the light emitting elements are not staggered.

Referring to (d) in FIGS. 7 and 8, when the first stagger distance w1 is about 8 μm, the first horizontal distance d1 between the even-numbered column light emitting element ED21 and the adjacent odd-numbered column light emitting elements ED11 and ED31 is greater than the conventional second horizontal distance d2 in the case where the light emitting elements are not staggered, so that light leakage can be reduced to about 17% compared to the cases of (a) to (c) in FIGS. 7 and 8.

Therefore, according to the present disclosure, since the plurality of light emitting elements ED11 and ED31 are vertically aligned with and overlap the plurality of lenses 610 positioned thereabove, and the adjacent plurality of light emitting elements ED21 are staggered by about 8 μm, light leakage through the lenses 610 positioned above the plurality of light emitting elements ED21 adjacent to the plurality of light emitting elements ED11 and ED31 can be reduced compared to a case where the adjacent light emitting elements are staggered by about 6 μm.

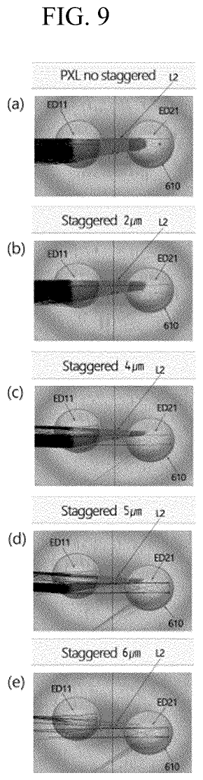

FIG. 9 is a diagram schematically illustrating light incident on adjacent pixels according to stagger distances between adjacent pixels in a display device according to one embodiment of the present disclosure.

Referring to (a) of FIG. 9, in a case where there is no staggered arrangement between the odd-numbered column light emitting elements ED11 and ED31 and the even-numbered column light emitting element ED21, it can be observed that leakage of light emitted toward the odd-numbered column light emitting elements ED11 and ED31 from the even-numbered column light emitting element ED21 increases.

In contrast, referring to (b) of FIG. 9, it can be observed that, as the even-numbered column light emitting element ED21 is spaced apart from the adjacent odd-numbered column light emitting elements ED11 and ED31 in the first direction X, which is the horizontal direction, and staggered by about 2 μm in the second direction Y, which is the vertical direction, leakage of light emitted from the even-numbered column light emitting element ED21 toward the adjacent odd-numbered column light emitting elements ED11 and ED31 is reduced compared to the case where the light emitting elements are not staggered as in (a) of FIG. 9.

Referring to (c) of FIG. 9, it can be observed that, as the even-numbered column light emitting element ED21 is spaced apart from the adjacent odd-numbered column light emitting elements ED11 and ED31 in the first direction X, which is the horizontal direction, and staggered by about 4 μm in the second direction Y, which is the vertical direction, leakage of light L2 emitted from the even-numbered column light emitting element ED21 toward the adjacent odd-numbered column light emitting elements ED11 and ED31 is reduced compared to the case where the light emitting elements are staggered by about 2 μm as in (b) of FIG. 9.

Referring to (d) in FIG. 9, it can be observed that, as the even-numbered column light emitting element ED21 is spaced apart from the adjacent odd-numbered column light emitting elements ED11 and ED31 in the first direction X, which is the horizontal direction, and staggered by about 5 μm in the second direction Y, which is the vertical direction, leakage of light emitted from the even-numbered column light emitting element ED21 toward the adjacent odd-numbered column light emitting elements ED11 and ED31 is reduced compared to the case where the light emitting elements are staggered by about 4 μm as in (c) of FIG. 9.

Referring to (e) in FIG. 9, it can be observed that, as the even-numbered column light emitting element ED21 is spaced apart from the adjacent odd-numbered column light emitting elements ED11 and ED31 in the first direction X, which is the horizontal direction, and staggered by about 6μm in the second direction Y, which is the vertical direction, leakage of light emitted from the even-numbered column light emitting element ED21 toward the adjacent odd-numbered column light emitting elements ED11 and ED31 is reduced compared to the case where the light emitting elements are staggered by about 5 μm as in (d) of FIG. 9.

As described above, according to the present disclosure, by arranging the plurality of light emitting elements that are vertically and horizontally adjacent to each other to be staggered, a horizontal distance between the adjacent light emitting elements can be increased, thereby minimizing light leakage toward the adjacent light emitting elements.

According to the present disclosure, the light emitting elements constituting pixels can be arranged to be vertically aligned with and overlap the lenses positioned thereabove and the adjacent light emitting elements can be arranged to be staggered, thereby reducing light leakage through adjacent lenses positioned above the adjacent light emitting elements.

According to the present disclosure, in a case where the plurality of light emitting elements and the light emitting elements arranged adjacent thereto are arranged to be staggered horizontally and vertically, as a horizontal distance between the adjacent light emitting elements is gradually increased from 2 μm to 8 μm, a peak of light leakage at a viewing angle between about 30° and 50° can gradually decrease from about 60% to about 20% or less.

The display device according to various embodiments of the present disclosure can be described as follows.

A display device according to various embodiments of the present disclosure can comprise a bank insulating film positioned on a substrate and defining a plurality of emission regions; a plurality of light emitting elements arranged in the plurality of emission regions of the substrate; an encapsulation member positioned on the plurality of light emitting elements; a plurality of lenses arranged over the encapsulation member and positioned above the plurality of light emitting elements; and a lens planarization layer positioned on the plurality of lenses, wherein light emitting elements adjacent to each other among the plurality of light emitting elements are arranged to be staggered in a horizontal direction and a vertical direction.

According to one embodiment of the present disclosure, a staggered pitch between the plurality of light emitting elements and light emitting elements arranged to be staggered between the plurality of light emitting elements can be equal to or greater than one-half of a size of the light emitting elements.

According to one embodiment of the present disclosure, the plurality of light emitting elements can include a red light emitting element, a green light emitting element, and a blue light emitting element.

According to one embodiment of the present disclosure, the plurality of light emitting elements can overlap the plurality of lenses.

According to one embodiment of the present disclosure, a first black matrix, a planarization layer, and a second black matrix can be positioned between the encapsulation member and the plurality of lenses.

According to one embodiment of the present disclosure, the first black matrix can include an organic material, and the second black matrix includes a metallic material.

According to one embodiment of the present disclosure, the second black matrix can include a touch electrode.

According to one embodiment of the present disclosure, the first black matrix and the second black matrix can overlap each other.

According to one embodiment of the present disclosure, a first horizontal distance between the plurality of light emitting elements that are arranged adjacent to and staggered from each other can be greater than a second horizontal distance between the plurality of light emitting elements that are aligned on the same line in a horizontal direction and a vertical direction without being staggered.

A display device according to various embodiments of the present disclosure can comprise a display panel in which a first light emitting element and a second light emitting element are repeatedly arranged in a first direction, and the first light emitting element and the second light emitting element are repeatedly arranged in a second direction perpendicular to the first direction; a plurality of lenses positioned above the first light emitting element and the second light emitting element; and a lens planarization layer positioned on the plurality of lenses, wherein the first light emitting element and the second light emitting element are arranged to be staggered in a horizontal direction and a vertical direction.

According to one embodiment of the present disclosure, a staggered pitch between the first light emitting element and the second light emitting element can be equal to or greater than one-half of a size of the first light emitting element and the second light emitting element.

According to one embodiment of the present disclosure, the first light emitting element and the second light emitting element can overlap the plurality of lenses.

According to one embodiment of the present disclosure, the display panel can include a bank insulating film positioned on a substrate and configured to separate the first light emitting element from the second light emitting element; an encapsulation member positioned on the first light emitting element and the second light emitting element; a first black matrix positioned on the encapsulation member; a planarization layer positioned on the first black matrix and the encapsulation member; and a second black matrix positioned on the planarization layer.

According to one embodiment of the present disclosure, the second black matrix can include a touch electrode.

According to one embodiment of the present disclosure, the first black matrix and the second black matrix can overlap each other.

According to one embodiment of the present disclosure, the first black matrix can include an organic material, and the second black matrix includes a metallic material.

According to one embodiment of the present disclosure, a first horizontal distance between the first light emitting element and the second light emitting element that are arranged adjacent to and staggered from each other can be greater than a second horizontal distance between the first light emitting element and the second light emitting element that are aligned on the same line in a horizontal direction and a vertical direction without being staggered.

According to one embodiment of the present disclosure, the display device can further include drivers configured to provide signals necessary for image generation to the display panel.

According to one embodiment of the present disclosure, the drivers can include a scan driver, a data driver, and a controller.

Although embodiments of the present disclosure have been described in more detail with reference to the accompanying drawings, the present disclosure is not necessarily limited to the embodiments, and various modifications can be carried out without departing from the technical spirit of the present disclosure.

Therefore, the embodiments disclosed in the present disclosure are not intended to limited the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A display device comprising:
a bank insulating film positioned on a substrate and defining a plurality of emission regions;
a plurality of light emitting elements arranged in the plurality of emission regions of the substrate;
an encapsulation member positioned on the plurality of light emitting elements;
a plurality of lenses arranged on the encapsulation member and positioned on the plurality of light emitting elements; and
a lens planarization layer positioned on the plurality of lenses,
wherein light emitting elements adjacent to each other among the plurality of light emitting elements are arranged to be staggered in a horizontal direction and a vertical direction.

2. The display device of claim 1, wherein a staggered pitch between the plurality of light emitting elements and the light emitting elements arranged to be staggered between the plurality of light emitting elements is equal to or greater than one-half of a size of the light emitting elements.

3. The display device of claim 1, wherein the plurality of light emitting elements include a red light emitting element, a green light emitting element, and a blue light emitting element.

4. The display device of claim 1, wherein the plurality of light emitting elements overlap the plurality of lenses.

5. The display device of claim 1, further comprising a first black matrix, a planarization layer, and a second black matrix positioned between the encapsulation member and the plurality of lenses.

6. The display device of claim 5, wherein the first black matrix includes an organic material, and the second black matrix includes a metallic material.

7. The display device of claim 5, wherein the second black matrix includes a touch electrode.

8. The display device of claim 5, wherein the first black matrix and the second black matrix overlap each other.

9. The display device of claim 1, wherein a first horizontal distance between the plurality of light emitting elements that are arranged adjacent to and staggered from each other is greater than a second horizontal distance between the plurality of light emitting elements that are aligned on a same line in the horizontal direction and the vertical direction without being staggered.

10. A display device comprising:
a display panel in which a first light emitting element and a second light emitting element are repeatedly arranged in a first direction, the first light emitting element and the second light emitting element being repeatedly arranged in a second direction crossing the first direction;
a plurality of lenses positioned on the first light emitting element and the second light emitting element; and
a lens planarization layer positioned on the plurality of lenses,
wherein the first light emitting element and the second light emitting element are arranged to be staggered in a horizontal direction and a vertical direction.

11. The display device of claim 10, wherein a staggered pitch between the first light emitting element and the second light emitting element is equal to or greater than one-half of a size of the first light emitting element and the second light emitting element.

12. The display device of claim 10, wherein the first light emitting element and the second light emitting element overlap the plurality of lenses.

13. The display device of claim 10, wherein the display panel includes:
a bank insulating film positioned on a substrate and configured to separate the first light emitting element from the second light emitting element;
an encapsulation member positioned on the first light emitting element and the second light emitting element;
a first black matrix positioned on the encapsulation member;
a planarization layer positioned on the first black matrix and the encapsulation member; and
a second black matrix positioned on the planarization layer.

14. The display device of claim 13, wherein the second black matrix includes a touch electrode.

15. The display device of claim 13, wherein the first black matrix and the second black matrix overlap each other.

16. The display device of claim 13, wherein the first black matrix includes an organic material, and the second black matrix includes a metallic material.

17. The display device of claim 10, wherein a first horizontal distance between the first light emitting element and the second light emitting element that are arranged adjacent to and staggered from each other is greater than a second horizontal distance between the first light emitting element and the second light emitting element that are aligned on a same line in the horizontal direction and the vertical direction without being staggered.

18. The display device of claim 10, further comprising:
a plurality of drivers configured to provide signals for image generation to the display panel.

19. The display device of claim 18, wherein the plurality of drivers include a scan driver, a data driver, and a controller.
